(19) United States
(12) Patent Application Publication
(10) Pub. No.: US 2025/0048593 A1
(43) Pub. Date: Feb. 6, 2025

(54) Vapor Chamber

(71) Applicant: Razer (ASIA-PACIFIC) PTE LTD., Singapore (SG)

(72) Inventors: ChengYu CHENG, Singapore (SG); YiHsiang HUNG, Singapore (SG)

(73) Assignee: Razer (ASIA-PACIFIC) PTE LTD., Singapore (SG)

(21) Appl. No.: 18/718,368

(22) PCT Filed: Feb. 18, 2022
(86) PCT No.: PCT/SG2022/050075

§ 371 Date: Jun. 10, 2024

(51) Int. Cl. H05K 7/20

(52) U.S. Cl. CPC H05K 7/20336; H05K 7/20172; H05K 7/20318; H05K 7/20409

(57) ABSTRACT

In some aspects, a vapor chamber includes a sealed enclosure. The sealed enclosure includes: a main portion defining a main chamber and a duct portion. The main portion has a heat input surface region for contacting a heat source. The duct portion extends from a first margin region of the main portion and returns to a second margin region of the main portion. The heat input surface region is between the first margin region and the second margin region of the main portion. The main portion and the duct portion form a closed loop structure.

### TECHNICAL FIELD

The present disclosure generally relates to a vapor chamber, in particular, a vapor chamber having a closed loop structure.

### BACKGROUND

The operation of electronic devices requires satisfactory thermal management to ensure proper function. As electronic devices become heated, the devices can suffer from device degradation, functional failure, and lower lifespan.

A vapor chamber can be used for removing heat from an electronic device to the ambient. Vapor chambers make use of the heat pipe principle that combines the principles of thermal conductivity and phase transition to remove heat from an electronic device to the ambient. In a vapor chamber, a working fluid in contact with a first surface of the vapor chamber (e.g., a surface of the vapor chamber in contact with a heat source of the electronic device) turns into a vapor by absorbing heat from that surface. The vapor then travels within the vapor chamber to a second, cooler surface of the vapor chamber and condenses back into a liquid, thus releasing the latent heat. The working fluid then returns to the first surface of the vapor chamber and the cycle repeats.

Therefore, there exists a need for vapor chambers that can efficiently dissipate heat from a heat source.

### SUMMARY

According to a first aspect of the present disclosure, a vapor chamber is provided. The vapor chamber may include a sealed enclosure. The sealed enclosure may include: a main portion defining a main chamber, the main portion having a heat input surface region for contacting a heat source; and a duct portion extending from a first margin region of the main portion and returning to a second margin region of the main portion, wherein the heat input surface region is between the first margin region and the second margin region of the main portion, wherein the main portion and the duct portion form a closed loop structure.

According to a second aspect of the present disclosure, a heat dissipating assembly is provided. The heat dissipating assembly may include a fan unit and a vapor chamber surrounding the fan unit. The vapor chamber may include a sealed enclosure. The sealed enclosure may include: a main portion defining a main chamber, the main portion having a heat input surface region for contacting a heat source; and a duct portion extending from a first margin region of the main portion and returning to a second margin region of the main portion, wherein the heat input surface region is between the first margin region and the second margin region of the main portion, wherein the main portion and the duct portion form a closed loop structure to surround the fan unit.

According to a third aspect of the present disclosure, an electronic device is provided. The electronic device may include a heat generating electronic component, a fan unit and a vapor chamber surrounding the fan unit. The heat generating electronic component may be in contact with a heat input surface region of the vapor chamber. The vapor chamber may include a sealed enclosure. The sealed enclosure may include: a main portion defining a main chamber, the main portion having the heat input surface region in contact with the heat source; and a duct portion extending from a first margin region of the main portion and returning to a second margin region of the main portion, wherein the heat input surface region is between the first margin region and the second margin region of the main portion, wherein the main portion and the duct portion form a closed loop structure to surround the fan unit.

### BRIEF DESCRIPTION OF THE DRAWINGS

FIG. 1 is a block diagram showing an example electronic device, according to an implementation of the present disclosure.

FIG. 2 is a schematic diagram showing a structure of an example circuit board, according to an implementation of the present disclosure.

FIG. 3 is a diagram showing a top-down view of a prior art vapor chamber.

FIG. 4A is a diagram showing a perspective view of an example vapor chamber that may be included in an electronic device, according to an implementation of the present disclosure; FIG. 4B is a diagram showing an exploded three-dimensional view of the example vapor chamber shown in FIG. 4A.

FIG. 5 is a diagram showing a top-down view of the example vapor chamber shown in FIG. 4A, according to an implementation of the present disclosure.

FIGS. 6A, 6B, 6C are diagrams showing cross-sectional views of the example vapor chamber shown in FIG. 4A, according to an implementation of the present disclosure.

FIGS. 7A, 7B, 7C are diagrams showing an example flow of working fluid in the example vapor chamber of FIGS. 6A, 6B, 6C when a processor is in operation, according to an implementation of the present disclosure.

FIG. 8 is a diagram showing an example flow of working fluid in the example vapor chamber of FIG. 4A when a processor is in operation, according to an implementation of the present disclosure.

FIG. 9 is a diagram showing a top-down view of an example vapor chamber, according to another implementation of the present disclosure.

FIG. 10 is a diagram showing a top-down view of an example vapor chamber, according to another implementation of the present disclosure.

FIG. 11 is a diagram showing a top-down view of an example vapor chamber, according to another implementation of the present disclosure.

FIG. 12 is a diagram showing a top-down view of an example vapor chamber, according to another implementation of the present disclosure.

### DETAILED DESCRIPTION

Implementations described below in the context of a device, apparatus, or system are analogously valid for the respective methods, and vice versa. Furthermore, it will be understood that the implementations described below may be combined, for example, a part of one implementation may be combined with a part of another implementation.

It should be understood that the terms “on”, “over”, “top”, “bottom”, “down”, “side”, “back”, “left”, “right”, “front”, “lateral”, “side”, “up”, “down”, “vertical”, “horizontal” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various aspects of what is described here seek to provide a vapor chamber. The proposed vapor chamber may include a closed loop structure. The closed loop structure may be formed by extending a wing of a conventional T-shape vapor chamber to circulate back to a heat source. Accordingly, a working fluid within the proposed vapor chamber may be vaporized and flow from the heat source to a condenser area along the closed loop structure, condensed back to liquid state and flow back to the heat source through a loop path along the closed loop structure of the proposed vapor chamber.

According to some aspects, the proposed vapor chamber may include a single closed loop structure. According to some aspects, the proposed vapor may include two loop structures forming a shape similar to an infinity symbol. According to some aspects, the proposed vapor chamber may include two or more loops structures. According to some aspects, the proposed vapor chamber may have at least one condenser area along each closed loop structure. Each condenser area may include a heat exchange arrangement, for example one or more heat dissipation structures (such as fin structures). According to some aspects, the proposed vapor chamber may have two or more (or multiple) condenser areas along each closed loop structure.

In some aspects of what is described here, a vapor chamber may include a sealed enclosure including a main portion and a duct portion (or a first duct portion). The main portion and the duct portion may form the closed loop structure (or a first closed loop structure). The main portion may have a heat input surface region for contacting a heat source (or a first heat source), and the duct portion may extend from a first margin region (or border region or periphery region) of the main portion and return to a second margin region (or border region or periphery region) of the main portion. The heat input surface region may be between the first margin region and the second margin region of the main portion. The closed loop structure may be configured to enclose an air flow generator (e.g. a fan structure). The air flow generator may increase the air flow rate in the vicinity of the vapor chamber and accordingly, the rate of heat dissipation of the vapor chamber may be increased. Accordingly, with the closed loop structure surrounding the air flow generator, the air flow generator may increase the air flow rate along the entire closed loop structure of the proposed vapor chamber.

In addition, according to some aspects, the vapor chamber may include a further duct portion (or a second duct portion) disposed in a mirror image of the duct portion (or the first duct portion) and accordingly, the vapor chamber may include a further closed loop structure (or a second closed loop structure) formed by the main portion and the further duct portion, thereby accommodating a further heat source (or a second heat source). Accordingly, two separate heat sources (e.g. the first heat source and the second heat source) may be provided to the single main portion of the proposed vapor chamber, and two closed loop structures (e.g. the first loop structure and the second loop structure) may be formed by extending two separate duct portions (e.g. the first duct portion and the second duct portion) from the single main portion of the proposed vapor chamber and returning respective duct portions back to the single main portion of the proposed vapor chamber. Hence, the single main portion of the proposed vapor chamber may include two heat input surface regions. Thus, the two separate heat sources may share the common single main portion of the proposed vapor chamber for heat dissipation. It should be appreciated that the vaper chamber may receive more than two heat sources sharing the main portion of the sealed enclosure.

In some instances, aspects of the systems and techniques described here provide technical improvements and advantages over existing approaches. For example, the proposed vapor chamber including the closed loop structure provides an efficient path for the working fluid to transfer the heat from the heat source and dissipate it to the ambient or a heat sink. Specifically, the liquid path and the gas path of the working fluid do not substantially cross each other and interfere with each other, eliminating or substantially reducing the shear force effects on the return liquid exerted by the high-velocity vapor which may in turn cause entrainment of the return liquid by the vapor. Furthermore, the proposed vapor chamber is configured to enclose a fan structure which promotes the circulation of the air flow in the vicinity of the vapor chamber (e.g. all round the closed loop structure) and further improves the efficiency of the vapor chamber. Additionally, the proposed vapor chamber including the closed loop structure provides an extended space for disposing heat dissipation structures along the loop which in turn improves the efficiency of the vapor chamber. The proposed vapor chamber can also offer flexible design capabilities and can provide multiple loop structures and multiple heat dissipation structures for multiple heat sources in dependence on requirements.

The following examples pertain to various aspects of the present disclosure.

Example 1 is a vapor chamber including: a sealed enclosure including: a main portion defining a main chamber, the main portion having a heat input surface region for contacting a heat source; and a duct portion extending from a first margin region of the main portion and returning to a second margin region of the main portion, wherein the heat input surface region is between the first margin region and the second margin region of the main portion, wherein the main portion and the duct portion form a closed loop structure.

In Example 2, the subject matter of Example 1 may optionally include that at least one heat dissipation structure is disposed on a corresponding exterior surface of the duct portion of the vapor chamber.

In Example 3, the subject matter of Example 2 may optionally include that the at least one heat dissipation structure is spaced apart from each other.

In Example 4, the subject matter of any one of Examples 2 to 3 may optionally include that each of the at least one the heat dissipation structure includes a fin structure.

In Example 5, the subject matter of any one of Examples 2 to 4 may optionally include that heat from the heat source in contact with the heat input surface region is transferred to a working fluid within the sealed enclosure via the heat input surface region to convert the working fluid from a liquid state to a gaseous state; and that the working fluid in the gaseous state is condensed back into the liquid state along the duct portion of the vapor chamber, wherein an interior surface of the duct portion, which is opposite the corresponding exterior surface of the duct portion having the at least one heat dissipation structure, serves as a condensing surface.

In Example 6, the subject matter of Example 5 may optionally include that a gas path is formed in a first direction from the main portion to the duct portion and a liquid path is formed in a second direction from the duct portion to the main portion.

In Example 7, the subject matter of Example 6 may optionally include that the liquid path and the gas path form a closed loop path.

In Example 8, the subject matter of any one of Examples 1 to 7 may optionally include that the closed loop structure is of a substantially rectangular annulus shape, wherein the main portion defines one side of the rectangular annulus shape and the duct portion defines remaining three sides of the rectangular annulus shape.

In Example 9, the subject matter of any one of Examples 1 to 8 may optionally include that the main portion includes: a further heat input surface region adjacent to the heat input surface region on a side of the heat input surface region opposite the duct portion; and a further duct portion extending from the first margin region of the main portion and returning to the second margin region of the main portion, wherein the further duct portion is at a side of the main portion opposite the duct portion, wherein the further heat input surface region is between the first margin region and the second margin region of the main portion, wherein the main portion and the further duct portion form a further closed loop structure.

In Example 10, the subject matter of Example 9 may optionally include that the further closed loop structure is a mirror image of the closed loop structure.

Example 11 is a heat dissipating assembly, including: a fan unit; and a vapor chamber surrounding the fan unit, the vapor chamber including: a sealed enclosure including: a main portion defining a main chamber, the main portion having a heat input surface region for contacting a heat source; and a duct portion extending from a first margin region of the main portion and returning to a second margin region of the main portion, wherein the heat input surface region is between the first margin region and the second margin region of the main portion, wherein the main portion and the duct portion form a closed loop structure to surround the fan unit.

In Example 12, the subject matter of Example 11 may optionally include that at least one heat dissipation structure is disposed on a corresponding exterior surface of the duct portion of the vapor chamber.

In Example 13, the subject matter of Example 12 may optionally include that the at least one heat dissipation structure is spaced apart from each other.

In Example 14, the subject matter of any one of Examples 12 to 13 may optionally include that each of the at least one the heat dissipation structure includes a fin structure.

In Example 15, the subject matter of any one of Examples 12 to 14 may optionally include that heat from the heat source in contact with the heat input surface region is transferred to a working fluid within the sealed enclosure via the heat input surface region to convert the working fluid from a liquid state to a gaseous state; and wherein the working fluid in the gaseous state is condensed back into the liquid state along the duct portion of the vapor chamber, wherein an interior surface of the duct portion, which is opposite the corresponding exterior surface of the duct portion having the at least one heat dissipation structure, serves as a condensing surface.

In Example 16, the subject matter of Example 15 may optionally include that a gas path is formed in a first direction from the main portion to the duct portion and a liquid path is formed in a second direction from the duct portion to the main portion.

In Example 17, the subject matter Example 16 may optionally include that the liquid path and the gas path form a closed loop path.

In Example 18, the subject matter of any one of Examples 11 to 17 may optionally include that the closed loop structure is of a substantially rectangular annulus shape, wherein the main portion defines one side of the rectangular annulus shape and the duct portion defines remaining three sides of the rectangular annulus shape.

In Example 19, the subject matter of any one of Examples 11 to 18 may optionally include that the main portion includes: a further heat input surface region adjacent to the heat input surface region on a side of the heat input surface region opposite the duct portion; and a further duct portion extending from the first margin region of the main portion and returning to the second margin region of the main portion, wherein the further duct portion is at a side of the main portion opposite the duct portion, wherein the further heat input surface region is between the first margin region and the second margin region of the main portion, wherein the main portion and the further duct portion form a further closed loop structure.

In Example 20, the subject matter of Example 19 may optionally include that the further closed loop structure is a mirror image of the closed loop structure.

Example 21 is an electronic device, including: a heat generating electronic component; a fan unit; and a vapor chamber surrounding the fan unit, wherein the heat generating electronic component is in contact with a heat input surface region of the vapor chamber, the vapor chamber including: a sealed enclosure including: a main portion defining a main chamber, the main portion having the heat input surface region in contact with the heat source; and a duct portion extending from a first margin region of the main portion and returning to a second margin region of the main portion, wherein the heat input surface region is between the first margin region and the second margin region of the main portion, wherein the main portion and the duct portion form a closed loop structure to surround the fan unit.

In Example 22, the subject matter of Example 21 may optionally include that at least one heat dissipation structure is disposed on a corresponding exterior surface of the duct portion of the vapor chamber.

In Example 23, the subject matter of Example 22 may optionally include that the at least one heat dissipation structure is spaced apart from each other.

In Example 24, the subject matter of any one of Examples 22 to 23 may optionally include that each of the at least one the heat dissipation structure includes a fin structure.

In Example 25, the subject matter of any one of Examples 22 to 24 may optionally include that heat from the heat source in contact with the heat input surface region is transferred to a working fluid within the sealed enclosure via the heat input surface region to convert the working fluid from a liquid state to a gaseous state; and wherein the working fluid in the gaseous state is condensed back into the liquid state along the duct portion of the vapor chamber, wherein an interior surface of the duct portion, which is opposite the corresponding exterior surface of the duct portion having the at least one heat dissipation structure, serves as a condensing surface.

In Example 26, the subject matter of Example 25 may optionally include that a gas path is formed in a first direction from the main portion to the duct portion and a liquid path is formed in a second direction from the duct portion to the main portion.

In Example 27, the subject matter of Example 26 may optionally include that the liquid path and the gas path form a closed loop path.

In Example 28, the subject matter of any one of Examples 21 to 27 may optionally include that the closed loop structure is of a substantially rectangular annulus shape, wherein the main portion defines one side of the rectangular annulus shape and the duct portion defines remaining three sides of the rectangular annulus shape.

In Example 29, the subject matter of any one of Examples 21 to 28 may optionally include that the main portion includes: a further heat input surface region adjacent to the heat input surface region on a side of the heat input surface region opposite the duct portion; and a further duct portion extending from the first margin region of the main portion and returning to the second margin region of the main portion, wherein the further duct portion is at a side of the main portion opposite the duct portion, wherein the further heat input surface region is between the first margin region and the second margin region of the main portion, wherein the main portion and the further duct portion form a further closed loop structure.

In Example 30, the subject matter of any one of Examples 21 to 29 may optionally include that the further closed loop structure is a mirror image of the closed loop structure.

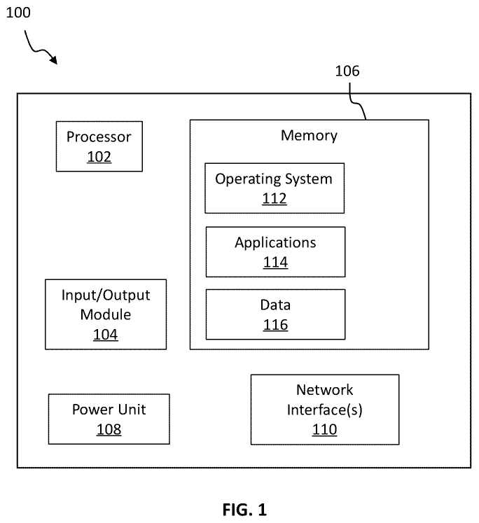

FIG. 1 is a block diagram showing an example electronic device 100, according to an implementation of the present disclosure. The electronic device 100 may be a laptop computer, a desktop computer, a tablet computer, an automobile computer, a game console, a smart phone, a personal digital assistant, a server, or other electronic devices capable of running computer applications. In some implementations, the electronic device 100 includes a processor 102, an input/output (I/O) module 104, memory 106, a power unit 108, and one or more network interfaces 110. The electronic device 110 can include additional components. In some implementations, the processor 102, input/output (I/O) module 104, memory 106, power unit 108, and the network interface(s) 110 are housed together in a common housing or other assembly.

The example processor 102 can execute instructions, for example, to generate output data based on data inputs. The instructions can include programs, codes, scripts, modules, or other types of data stored in memory (e.g., memory 106). Additionally or alternatively, the instructions can be encoded as pre-programmed or re-programmable logic circuits, logic gates, or other types of hardware or firmware components or modules. The processor 102 may be, or may include, a multicore processor having a plurality of cores, and each such core may have an independent power domain and can be configured to enter and exit different operating or performance states based on workload. Additionally or alternatively, the processor 102 may be, or may include, a general-purpose microprocessor, as a specialized co-processor or another type of data processing apparatus. In some cases, the processor 102 performs high-level operation of the electronic device 100. For example, the processor 102 may be configured to execute or interpret software, scripts, programs, functions, executables, or other instructions stored in the memory 106.

The example I/O module 104 may include a mouse, keypad, touch screen, scanner, optical reader, and/or stylus (or other input device(s)) through which a user of the electronic device 100 may provide input to the electronic device 100, and may also include one or more of a speaker for providing audio output and a video display device for providing textual, audiovisual, and/or graphical output.

The example memory 106 may include computer-readable storage media, for example, a volatile memory device, a non-volatile memory device, or both. The memory 106 may include one or more read-only memory devices, random-access memory devices, buffer memory devices, or a combination of these and other types of memory devices. In some instances, one or more components of the memory can be integrated or otherwise associated with another component of the electronic device 100. The memory 106 may store instructions that are executable by the processor 102. In some examples, the memory 106 may store instructions for an operating system 112 and for application programs 114. The memory 106 may also store a database 116.

The example power unit 108 provides power to the other components of the electronic device 100. For example, the other components may operate based on electrical power provided by the power unit 108 through a voltage bus or other connection. In some implementations, the power unit 108 includes a battery or a battery system, for example, a rechargeable battery. In some implementations, the power unit 108 includes an adapter (e.g., an AC adapter) that receives an external power signal (from an external source) and coverts the external power signal to an internal power signal conditioned for a component of the electronic device 100. The power unit 108 may include other components or operate in another manner.

The electronic device 100 may be configured to operate in a wireless, wired, or cloud network environment (or a combination thereof). In some implementations, the electronic device 100 can access the network using the network interface(s) 110. The network interface(s) 110 can include one or more adapters, modems, connectors, sockets, terminals, ports, slots, and the like. The wireless network that the electronic device 100 accesses may operate, for example, according to a wireless network standard or another type of wireless communication protocol. For example, the wireless network may be configured to operate as a Wireless Local Area Network (WLAN), a Personal Area Network (PAN), a metropolitan area network (MAN), or another type of wireless network. Examples of WLANs include networks configured to operate according to one or more of the 802.11 family of standards developed by IEEE (e.g., Wi-Fi networks), and others. Examples of PANs include networks that operate according to short-range communication standards (e.g., BLUETOOTH®, Near Field Communication (NFC), ZigBee), millimeter wave communications, and others. The wired network that the electronic device 100 accesses may, for example, include Ethernet, SONET, circuit-switched networks (e.g., using components such as SS7, cable, and the like), and others.

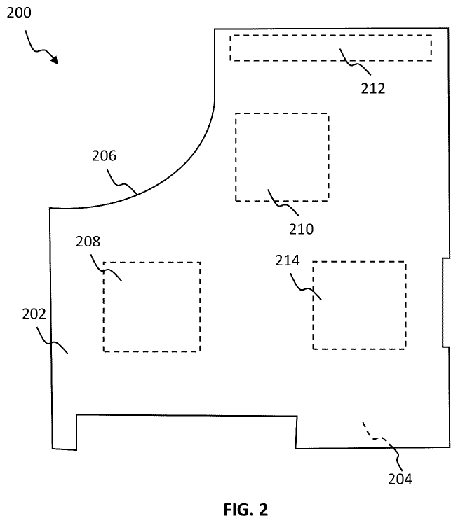

In some implementations, the various components of the electronic device 100 may be disposed on one or more planar surfaces of a circuit board (e.g., a motherboard) that electrically and communicatively connects the various components of the electronic device 100 to one another. FIG. 2 is a schematic diagram showing a structure of an example circuit board 200, according to an implementation of the present disclosure. The shape of the circuit board 200 shown in FIG. 2 is merely exemplary; the shape of the circuit board 200 may be different in other implementations. The circuit board 200 may be a motherboard of the electronic device 100 and may include a first (e.g., a top) surface 202 and a second (e.g., a bottom), opposing surface 204. In some instances, the circuit board 200 may define a cutout 206 in a corner of the circuit board 200. In the example of FIG. 2, the circuit board 200 includes a first area 208, a second area 210, a third area 212, and a fourth area 214. The areas 208, 210, 212, 214 shown in the FIG. 2 are merely exemplary, and the number of areas and their relative positions may be different in other implementations. The areas 208, 210, 212, 214 may be configured to receive various components of the electronic device 100, examples being the processor 102, I/O module 104, memory 106, power unit 108, and the network interface(s) 110 shown in FIG. 1. In some instances, these components of the electronic device 100 may be mounted on the circuit board 200, and the circuit board 200 may connect one or more hardware components of the electronic device 100 to the processor 102, distribute power from the power unit 108, or define the types of storage devices, memory modules, and graphics cards (among other expansion cards) that can connect to other components of the electronic device 100.

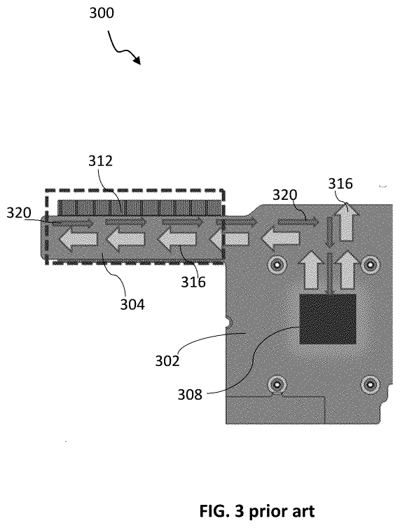

FIG. 3 is a diagram showing a top-down view of the prior art vapor chamber 300. The vapor chamber 300 is a chamber, including a main portion 302, a wing portion 304. Heat source 308 is located in the vicinity of the vapor chamber 300. In operation, the heat from the heat source 308 is transferred to the working fluid of the vapor chamber 300 and the working fluid converts from liquid state into gaseous state. As illustrated by arrows 316 the hot vapor, i.e. the working fluid in gaseous state, flows away from the heat source 308 to condenser area 312, and cools down into liquid state. As illustrated by arrows 320, the liquid, i.e. the working fluid in liquid state, flows back to the region in the vicinity of the heat source 308 along the same path of the vapor. For vapor chamber/heat pipe (two phases flow system), there is a limit that the vapor velocity increases with temperature and may be sufficiently high to produce shear force effects on the liquid return flow from the condenser to the evaporator (heat source), which cause entrainment of the liquid by the vapor and the liquid cannot go back to heat sources smoothly.

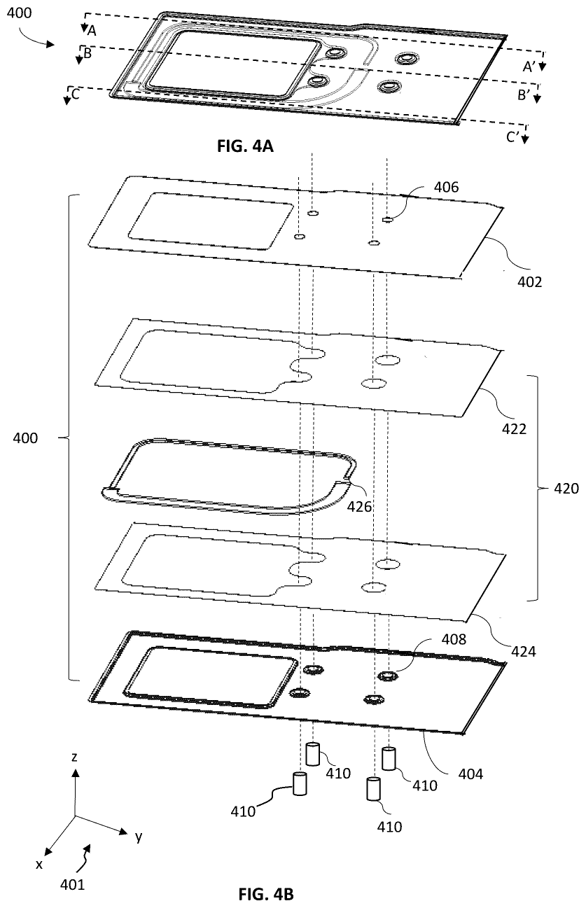

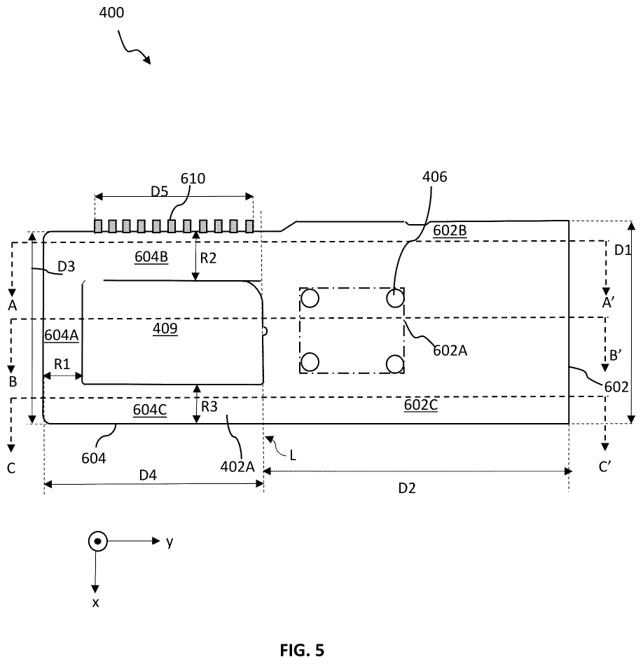

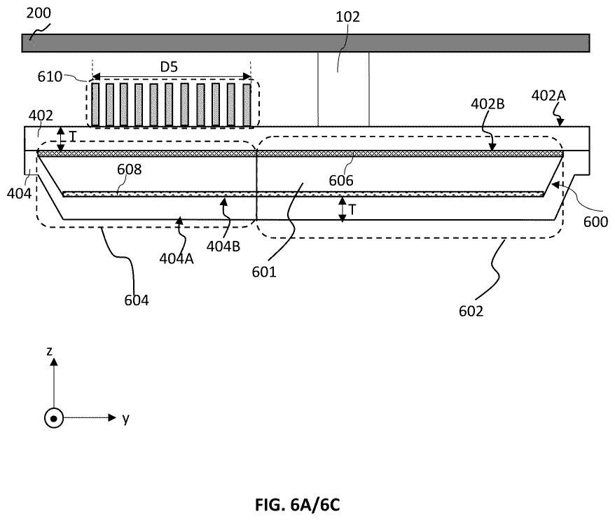

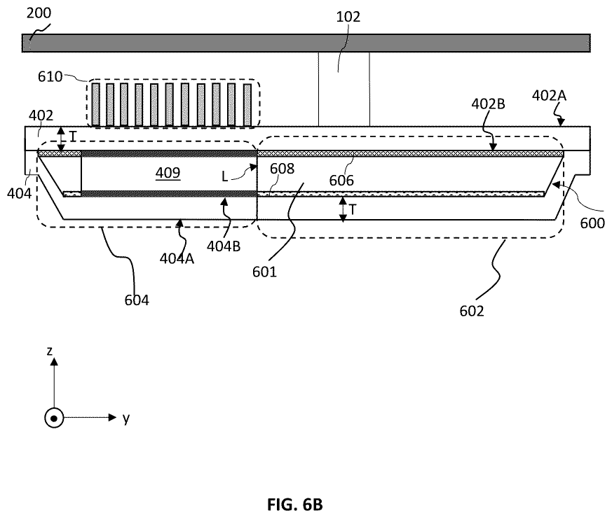

FIG. 4A is a diagram showing a perspective view of an example vapor chamber 400 that may be included in an electronic device, according to an implementation of the present disclosure; FIG. 4B is a diagram showing an exploded three-dimensional view of the example vapor chamber 400. FIG. 4B also shows a frame of reference 401 having three orthogonal axes. The frame of reference 401 includes a first axis in a first direction (e.g., the X-direction), a second axis in a second direction (e.g., the Y-direction), and a third axis in a third direction (e.g., the Z-direction). The first, second, and third directions are perpendicular to each other. FIG. 5 is a diagram showing a top-down view of the example vapor chamber 400 shown in FIG. 4A, according to an implementation of the present disclosure. FIGS. 6A, 6B, 6C are diagrams showing cross-sectional views of the example vapor chamber 400 shown in FIG. 4A, according to an implementations of the present disclosure. FIGS. 6A, 6B, 6C also show the relative positions of the vapor chamber 400, the processor 102, and the circuit board 200, according to an implementation of the present disclosure. The cross-sectional views shown in FIGS. 6A, 6B, 6C are taken along the line A-A′, B-B′ and C-C′ shown in FIGS. 4A and 5, respectively.

In contrast to prior art vapor chamber as shown in FIG. 3, the vapor chamber 400 proposed in this disclosure is optimized to efficiently dissipate heat from the processor 102. As an example, as described in further detail below, the vapor chamber 400 provides a fluid path in the evaporation-condensation cycles in which the liquid path and the gas path do not repeat each other and, therefore, the liquid and gas do not significantly interfere with each other. Furthermore, although various aspects of the present disclosure described efficiently dissipate heat from the processor 102, the vapor chamber 400 can be used for any component in an electronic device.

As seen in FIGS. 4A, 4B, 5, and 6A, 6B, 6C, and in some aspects, the vapor chamber 400 may include a cover portion 402 and a base portion 404. In some implementations, the cover portion 402 and the base portion 404 may be formed from one or more materials having high thermal conductivity (e.g., a material having thermal conductivity greater than or equal to about 200 W/m K). Example materials having high thermal conductivity include copper and aluminum. In some implementations, each of the cover portion 402 and the base portion 404 has a thickness T (e.g., measured in the third direction) that may be in a range from about 0.08 mm to about 1.0 mm). In some aspects, the vapor chamber 400 may also include the wick structure arrangement 420. It should be appreciated that the wick structure arrangement 420 shown in FIG. 4B comprises wick structures 422, 424 and 426, but it is not limited to such an arrangement of wick structures and the wick structure arrangement of the vapor chamber 400 can include the single wick structure 426, a combination of wick structures 422, 424, a combination of wick structures 422, 426, a combination of wick structures 424, 426, or more than three wick structures.

In some aspects, the cover portion 402 may have a first surface 402A and a second surface 402B opposite the first surface 402A. Similarly, the base portion 404 may have a first surface 404A and a second surface 404B opposite the first surface 404A. The first surfaces 402A, 404A of the cover and base portions 402, 404 may define the exterior surfaces of the vapor chamber 400. In various aspects, the cover portion 402 and the base portion 404 may be secured to each other to form a sealed, interior enclosure under vacuum pressure that contains one or more capillary structures and a working fluid under pressure that circulates within the sealed enclosure. For example, as seen in FIGS. 6A, 6B, 6C, a sealed enclosure 600 may be defined by the second surface 402B of the cover portion 402 and the second surface 404B of the base portion 404.

As seen in FIG. 4B, in some aspects, the cover portion 402 may include through holes 406, and the base portion 404 may include through holes 408 that are aligned to the through holes 406. In some instances, the through holes 406, 408 can accommodate screws 410 that can secure the cover portion 402 and the base portion 404 to each other, thereby forming the sealed enclosure 600 of the vapor chamber 400. In some instances, the circuit board 200 may also include through holes that are aligned to the through holes 406, 408. In such instances, the screws 410 may also be used to secure the vapor chamber 400 to the circuit board 200 such that a heat generating component of the circuit board 200 (e.g. the processor 102) is in physical contact with the surface 402A of the cover portion 402 (e.g., as seen in the example of FIGS. 6A, 6B, 6C).

The vapor chamber 400 (e.g., the sealed enclosure 600 of the vapor chamber 400) may include a main portion 602. The main portion may define a main chamber. In some implementations, the processor 102 is in physical contact with the surface 402A of the cover portion 402 in a manner that the processor 102 is disposed over and in physical contact with a heat input surface region 602A of the main portion 602. The heat input surface region 602A of the main portion 602 may be defined by a region between the though holes 406. The heat input surface region 602A may be the region of the surface 402A of the cover portion 402 which is in physical contact with the heat generating component of the circuit board 200 (e.g. the processor 102). The main portion 602 may have a dimension D1 in the first direction (e.g., the farthest lateral extent in the X-direction) and a dimension D2 in the second direction (e.g., the farthest lateral extent in the Y-direction).

The vapor chamber 400 (e.g., the sealed enclosure 600 of the vapor chamber 400) may also include a duct portion 604 extending from a first margin region 602B (or border region or periphery region) of the main portion 602 and returning to a second margin region 602C (or border region or periphery region) of the main portion 602. The duct portion 604 may be in the form of a tube-like, or a pipe-like or a conduit-like structure extending from the main portion 602 and returning back to the main portion 602. Accordingly, the duct portion 604 may form a return path or a circulation path extending from one region (e.g. the first margin region 602B) of the main portion 602 and returning to another region (e.g. the second margin region 602C) of the main portion 602. The duct portion 604 may have a rectilinear arrangement or may be arcuate. The heat input surface region 602A may be between the first margin region 602B and the second margin region 602C of the main portion 602. Accordingly, the heat input surface region 602A may be located at an intervening space or an intermediate position between the first margin region 602B and the second margin region 602C of the main portion 602. The first margin region 602B of the main portion 602 may be defined by an upper region of the main portion 602 as shown in FIG. 5, and the second margin region 602C of the main portion 602 may be defined by a lower region of the main portion 602 as shown in FIG. 5. Accordingly, the first margin region 602B and the second margin region 602C of the main portion 602 may be on two opposite sides of the heat input surface region 602A.

In some implementations, when the duct portion 604 is of the rectilinear arrangement, the duct portion 604 may include a vertical side 604A and two horizontal sides 604B, 604C. A first horizontal side 604B of the duct portion 604 extends from the first margin region 602B of the main portion 602 and a second horizontal side 604C of the duct portion 604 extends from the second margin region 602C of the main portion 602. The vertical side 604A interconnects the two horizontal sides 604B, 604C in a manner such that the duct portion 604 may form the return path or the circulation path external to the main portion 602.

The vertical side 604A of the duct portion 604 may have a dimension D3 in the first direction (e.g., the farthest lateral extent in the X-direction) and a thickness R1 in the second direction. The two horizontal sides 604B, 604C, of the duct portion 604 may have a dimension D4 in the second direction (e.g., the farthest lateral extent in the Y-direction) and a thickness R2, R3, respectively in the first direction. It should be appreciated that the two horizontal sides 604B, 604C, of the duct portion 604 are shown to have the same dimension D4, but they can have different dimensions. For example, the dimension of the horizontal side 604B is larger than the dimension of the horizontal side 604C. Additionally, the thickness R2 of the horizontal side 604B may be larger than the thicknesses R1 and/or R3, of the vertical side 604A and the horizontal side 604B. A larger thickness and/or a larger length of the horizontal side 604B may provide a larger contact space (i.e. condense surface) for the vapor to be in contact with the cooler surface and condense into liquid, and for the liquid to be captured by capillary action. Further, the thickness R2 of the horizontal side 604B may be different from a dimension in the first direction of the first margin region 602B; for example, R2 can be smaller or larger than the dimension in the first direction of the first margin region 602B. Similarly, the thickness R3 of the horizontal side 604C may be different from a dimension in the first direction of the second margin region 602C; for example, R3 can be smaller or larger than the dimension in the second direction of the second margin region 602C. Furthermore, a border or periphery of the horizontal side 604B may not be in alignment with a border or periphery of the first margin region 602B; similarly, a border or periphery of the horizontal side 604C may not be in alignment with a border or periphery of the second margin region 602C.

The main portion 602 and the duct portion 604 may form the closed loop structure. The closed loop structure is shown as a substantially rectangular annulus shape, wherein the main portion 602 defines one side of the rectangular annulus shape and the duct portion 604 (e.g. the vertical side 604A, the two horizontal sides 604B, 604C) defines remaining three sides of the rectangular annulus shape. It should be appreciated that although in the example of FIGS. 4A, 4B, 5, and 6A, 6B, 6C, the main portion 602 forms a right side of the rectangular annulus, the main portion 602 can be any side of the rectangular annulus as long as it forms a portion of the rectangular annulus. It should be also appreciated that the closed loop structure may also include a ring shaped structure when the duct potion 604 is of an arcuate shape and a trapezoid shape when the two horizontal sides are of different dimensions.

The closed loop structure may define an opening 409 therewithin. Accordingly, closed loop structure surrounds or encircles the opening 409. In some instances, such as in the example of FIGS. 4A, 4B 5, and 6A, 6B, 6C, a right side of the opening 409 may define the boundary L between the main portion 602 and the duct portion 604. In some instances, the dimensions D2 and D4 may be measured relative to the boundary L between the main portion 602 and the duct portion 604, as seen in FIG. 5. In other words, the duct portion 604 is located to the left of the boundary L and the main portion is located to the right of the boundary L.

In some implementations, the vapor chamber 400 includes a first capillary structure 606 that lines the second surface 402B of the cover portion 402, and a second capillary structure 608 that lines the second surface 404B of the base portion 404. The surface 402B of the cover portion 402 may be referred to as a first interior surface of the sealed enclosure 600, and the surface 404B of the base portion 404 may be referred to as a second interior surface of the sealed enclosure 600. The first and second capillary structures 606, 608 may be separated from each other (e.g., in the third direction) by an air gap 601. In some instances, the first and second capillary structures 606, 608 is evenly (e.g., conformally) formed over an entirety of the surfaces 402B, 404B, respectively, such that the first and second capillary structures 606, 608 are disposed in the main portion 602, the duct portion 604 of the sealed enclosure 600.

The first and second capillary structures 606, 608 may be porous wick structures configured to circulate a working fluid in the sealed enclosure 600 by capillary forces. The first capillary structure 606 may be similar to the wick structure 422 as shown in FIG. 4B and the second capillary structure 608 may be similar to the wick structure 424 as shown in FIG. 4B. In some instances, the first and second capillary structures 606, 608 may be formed from one or more metals (e.g., copper) and may be in a form of a sintered metal-containing powder, one or more layers of a metal-containing mesh, one or more layers of a metal-containing foam, a metal-containing fiber structure, or a combination thereof. Furthermore, the working fluid used in the sealed enclosure 600 may be water (e.g., distilled water), although other types of working fluid are possible (e.g., a refrigerant, alcohol, ammonia, etc.). In some implementations, the first and second capillary structures 606, 608 are saturated with the working fluid, and the cover and base portions 402, 404 (e.g., having the saturated first and second capillary structures 606, 608 lining the surfaces 402B, 404B thereof) are secured to each other to form the sealed enclosure 600.

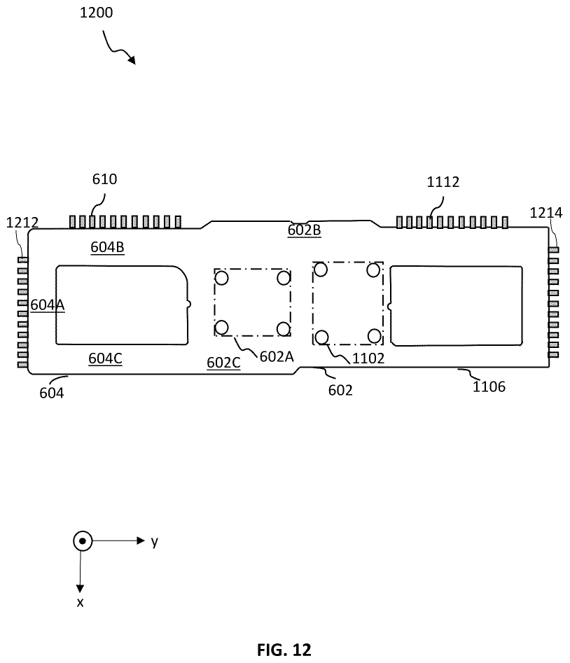

In some aspects, the vapor chamber 400 may also include at least one heat dissipation structure (e.g., a fin structure 610) formed on an exterior surface of the vapor chamber 400 for diffusing heat from the vapor chamber 400 to the ambient/outside environment or a heat sink. The at least one heat dissipation structure (e.g., a fin structure 610) may be along the duct portion 604 of the vapor chamber 400. The fin structures 610 may be formed from one or more materials having high thermal conductivity (e.g., a material having thermal conductivity greater than or equal to about 200 W/m K). Example materials having high thermal conductivity include copper and aluminum. The fin structure 610 shown in FIGS. 4A, 4B, 5, and 6A, 6B, 6C is merely exemplary, and other types, numbers, arrangements, etc. of fin structures may be possible in other implementations. It should be also appreciated that only one heat dissipation structure (e.g. fin structure 610) is shown in FIGS. 4A, 4B, 5, 6A, 6B, 6C, but more than one heat dissipation structure can be provided and each is disposed on a corresponding exterior surface of the duct portion 604 of the vapor chamber 400. Further, it should be appreciated that the at least one heat dissipation structure can be spaced apart from each other. Further details will be discussed in the following description with reference to FIG. 12.

The fin structure 610 may be disposed on either the first surface 402A of the cover portion 402 or the first surface 404A of the base portion 404. In some instances, the fin structure 610 may be disposed on both the first surface 402A of the cover portion 402 and the first surface 404A of the base portion 404. In the example shown in FIGS. 6A, 6B, 6C, the fin structure 610 may be positioned lateral to the processor 102 (e.g., in the second direction) and over the first surface 404A of the cover portion 402. In some implementations, a dimension D5 of the fin structures 610 in the second direction (e.g., the farthest lateral extent in the Y-direction) may be less than the dimension D4. Consequently, as seen in the examples of FIGS. 4A, 4B, 5, 6A, 6B 6C, the horizontal side 604B of the duct portion 604 extends laterally in the second direction beyond a footprint of the fin structure 610.

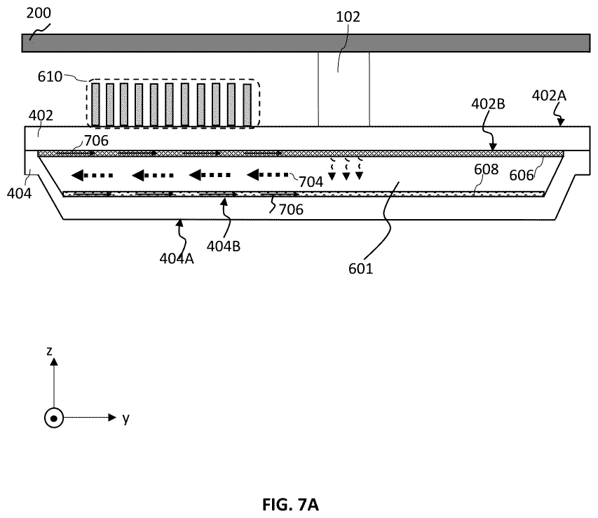

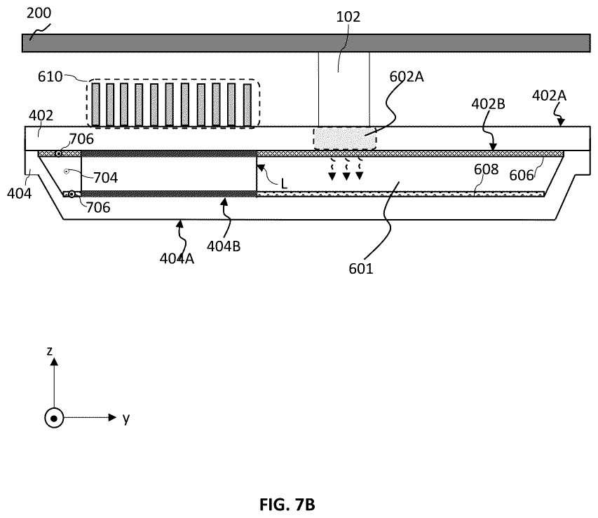

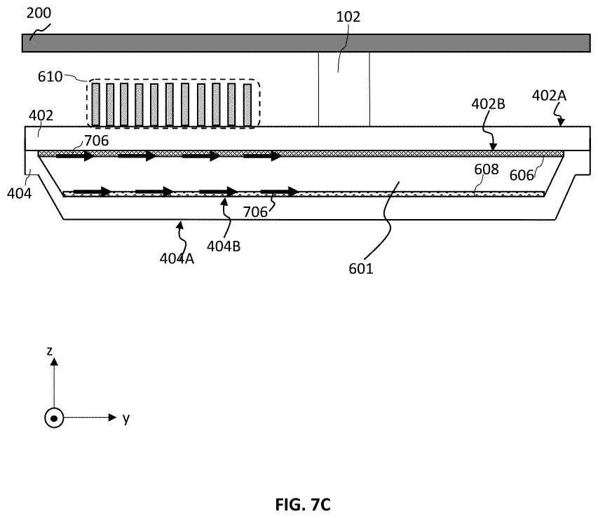

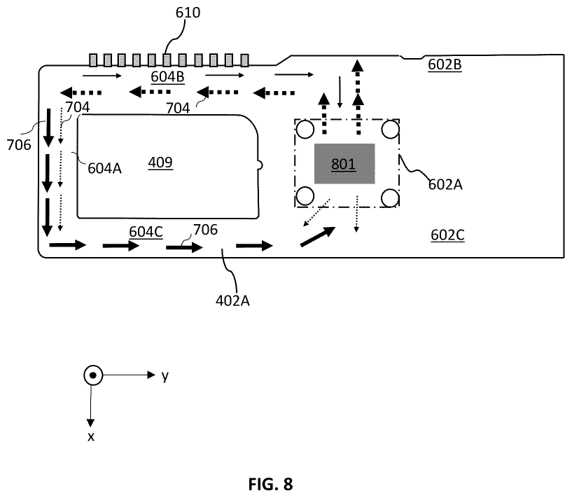

When the processor 102 is in operation, the vapor chamber 400 may dissipate the heat generated by the processor 102 by circulating the working fluid within the sealed enclosure 600 (e.g., through repeated evaporation-condensation cycles). FIGS. 7A, 7B, 7C, 8 are diagrams showing an example flow of working fluid in the vapor chamber 400 when the processor 102 is in operation, according to an implementation of the present disclosure. The cross-sectional views shown in FIGS. 7A, 7B, 7C are taken along the line A-A′, B-B′ and C-C′ shown in FIGS. 4A and 5, respectively. FIG. 8 shows a top-down view of the vapor chamber 400.

When the processor 102 is in a sleep or low power state, the vapor chamber 400 is not in operation and therefore, the working fluid is not experiencing evaporation or condensation within the sealed enclosure 600. Consequently, the working fluid within the sealed enclosure 600 is in a liquid state. Furthermore, the working fluid evenly saturates the first and second capillary structures 606, 608. Additionally, there is an equal, equilibrium vapor pressure experienced across the air gap 601.

Referring to FIGS. 7A and 8, when the processor 102 is in operation, the heat input surface region 602A of the vapor chamber 400 that is in physical contact with the processor 102 increases in temperature. Heat (denoted as 801) from the heat source (e.g. the processor 102) in contact with the heat input surface region 602A may be transferred to the working fluid within the sealed enclosure 600 via the heat input surface region 602A to convert the working fluid from a liquid state to a gaseous state. The latent heat of vaporization absorbed by the working fluid at the heat input surface region 602A reduces the temperature of the surrounding, thus dissipating heat from the processor 102. As the vapor travels through the sealed enclosure 600 from the main portion 602 (e.g. the first margin region 602B) to the horizontal side 604B of the duct portion 604 (e.g., illustrated by dash arrows 704), leaves the evaporation zone (e.g., an area in the vicinity of the processor 102 or the heat input surface region 602A) and enters a condensation zone (e.g., an area in the vapor chamber 400 away from the processor 102 or along the duct portion 604). An interior surface of the duct portion 604, which is opposite the exterior surface of the duct portion 604 having the at least one heat dissipation structure 610, may serve as a condensing surface for the condensation zone. In the condensation zone, the vapor condenses into liquid, thus releasing the latent heat into the walls of the vapor chamber 400. The liquid is then captured by portions of the first and second capillary structures 606, 608.

Referring FIGS. 7B and 8, the remaining vapor will continue travel along the closed loop structure to the vertical side 604A of the duct portion 604 (e.g., illustrated by dot 704 indicating traveling in the first direction) and condense into liquid as the temperature decreases. The liquid captured by the first and second capillary structures 606, 608 will also travel along the loop structure to the vertical side 604A (e.g., illustrated by dot 706 indicating traveling in the first direction) due to the capillary action and then to the horizontal side 604C of the duct portion 604 as shown in FIG. 7C (e.g., illustrated by solid arrows 706). As vaporization of the working fluid at the heat input surface region 602A occurs, working fluid (in the liquid state) is drawn from the condensation zone to the evaporation zone through the first and second capillary structures 606, 608 via capillary action. This evaporation-condensation cycle is repeated while the processor 102 is in operation.

As shown in FIGS. 7A, 7B, 7C and 8, a gas path is formed in a first direction (e.g. outwards and away from the main portion 602) from the main portion 602 to the horizontal side 604B of the duct portion 604 and a liquid path is formed in a second direction (e.g. inwards and towards the main portion 602) from the vertical side 604A of the duct portion 604 back to the main portion 602. The liquid path and the gas path form a closed loop path (e.g. an anticlockwise path). Differently from the prior art vapor chamber 300 as shown in FIG. 3, the proposed vapor chamber provides a closed loop path where the gas path is formed from the evaporation zone to the condensation zone, separately from the liquid path which is formed from the condensation zone to the evaporation zone. It is noted that a portion of the liquid may travel back to the evaporation zone along the same path of the gas path, that is, the horizontal side 604B of the duct portion 604, but as the amount of the portion of the liquid is relatively small, the entrainment of the liquid by the vapor is substantially reduced.

A research has been conducted to study the performance comparison between the prior art vapor chamber 300 and the proposed vapor chamber 400. Based on the research results, the prior art vapor chamber 300 can support two heat sources of 45 W and 90 W, and the proposed vapor chamber 400 having a loop structure can support two heat sources of 60 W and 120 W. A significant increase of the performance has been obtained for the proposed vapor chamber.

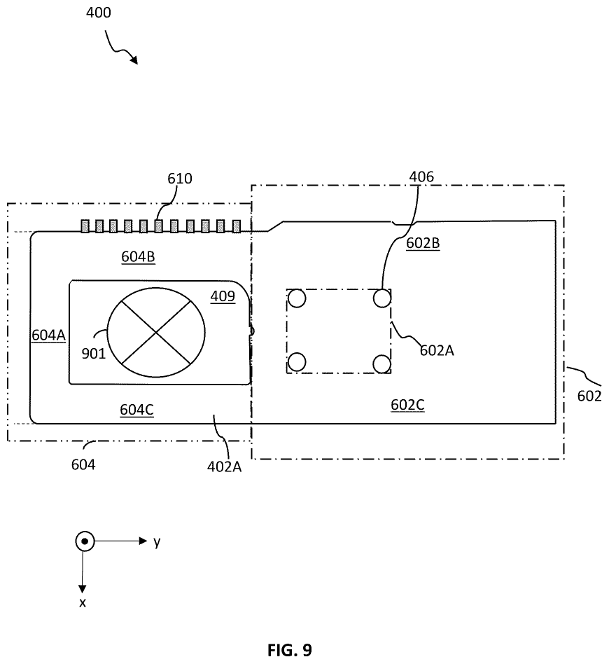

In some implementations, as shown in FIG. 9, the closed loop structure of the vapor chamber 400 is configured to enclose or surround or encircle an air flow generator, e.g. a fan structure 901, in the opening 409 of the loop structure. The fan structure 901 may be detachably attached to the vapor chamber 400 or integral with the vapor chamber 400. By utilizing a fan structure 901, the air circulation in the ambient of the vapor chamber improves which in turn increases the efficiency of heat dissipation of the vapor chamber 400. Additionally, enclosing the fan structure 901 by the closed loop structure of the vapor chamber 400 maximizes the cooling rate of the fan structure to the vapor chamber as the extended exterior surface of the vapor chamber (e.g. along the duct portion 406) is exposed to the fan structure 901.

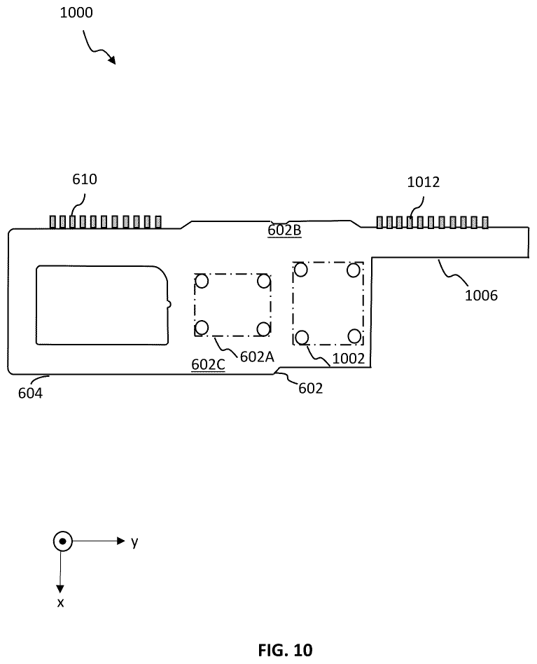

In some implementations, the structure of the vapor chamber 400 (e.g. as illustrated in the example of FIGS. 4A, 4B, 5 and 6A, 6B, 6C) may be modified as seen in FIGS. 10, 11 and 12. Similar to the vapor chamber 400 in the example of FIGS. 4A, 4B, 5, 6A, 6B, 6C in each of the examples shown in FIGS. 10, 11 and 12, the vapor chamber 1000, 1100, 1200 can provide a closed loop structure and, therefore, an interference-free path of the working fluid, and more efficient vapor chambers.

FIG. 10 is a diagram showing a top-down view of the example vapor chamber 1000, according to another implementation of the present disclosure. The vapor chamber 1000 may include the features of the vapor chamber 400 as described above in connection to FIGS. 4A, 4B, 5, 6A, 6B, 6C, and therefore, the common features are labelled with the same reference numerals and need not be discussed. The vapor chamber 1000 shown in FIG. 10 may include a main portion 602, a duct portion 604 and a wing portion 1006. The main portion 602 of the vapor chamber 1000 may also include a further heat input surface region 1002 adjacent to the heat input surface region 602A on a side of the heat input surface region 602A opposite the duct portion 604. The further heat input surface region 1002 is configured to be in physical contact with another heat source. The wing portion 1006 may extend from the first margin region 602B of the main portion 602 and is at a side of the main portion 602 opposite the duct portion 604, wherein the further heat input surface region 1002 is between the first margin region 602B and the second margin region 602C of the main portion 602. A fin structure 1012 may be disposed on an exterior surface of the wing portion 1006.

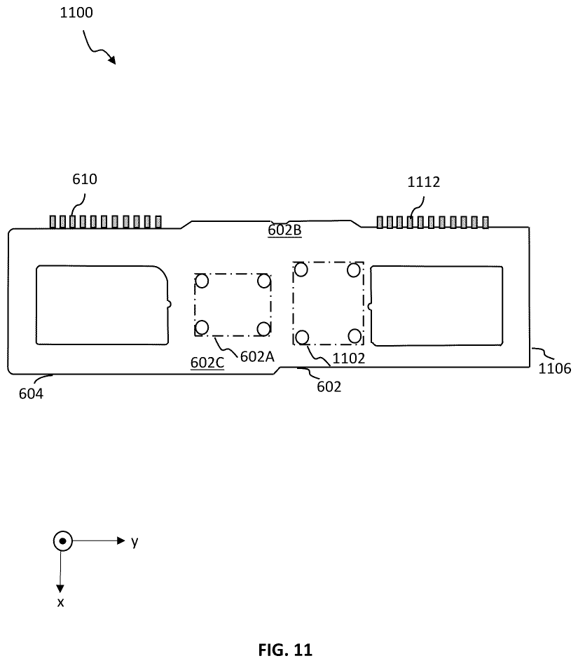

FIG. 11 is a diagram showing a top-down view of the example vapor chamber 1100, according to another implementation of the present disclosure. The vapor chamber 1100 may include the features of the vapor chamber 400 as described above in connection to FIGS. 4A, 4B, 5, 6A, 6B, 6C and therefore, the common features are labelled with the same reference numerals and need not be discussed. The vapor chamber 1100 shown in FIG. 11 may include a main portion 602, a duct portion 604 and a further duct portion 1106. The main portion 602 of the vapor chamber 1100 may also include a further heat input surface region 1102 adjacent to the heat input surface region 602A on a side of the heat input surface region 602A opposite the duct portion 604. The further heat input surface region 1102 is configured to be in physical contact with another heat source. The further duct portion 1106 may extend from the first margin region 602B of the main portion 602 and return to the second margin region 602C of the main portion 602, wherein the further duct portion 1106 is at a side of the main portion 602 opposite the duct portion 604, wherein the further heat input surface region 1102 is between the first margin region 602B and the second margin region 602C of the main portion 602, wherein the main portion 602 and the further duct portion 1106 form a further closed loop structure. The further closed loop structure may share a common main portion 602 with the closed loop structure. The further closed loop structure may be a mirror image of the closed loop structure. It should be appreciated that although the further loop structure is shown as a mirror image of the closed loop structure, the vapor chamber 1100 may have a further loop structure disposed on a side along the first or second margin region 602B, 602C of the main portion 602.

The vapor chamber 1100 may include a further heat dissipation structure (e.g., a fin structure 1112) formed on a further exterior surface of the vapor chamber 1100 for diffusing heat from the vapor chamber 1100 to the ambient/outside environment or a heat sink.

FIG. 12 is a diagram showing a top-down view of the example vapor chamber 1200, according to another implementation of the present disclosure. The vapor chamber 1200 may include the features of the vapor chamber 1100 as described above in connection to FIG. 11, and therefore, the common features are labelled with the same reference numerals and need not be discussed. The duct portion 604 of the vapor chamber 1200 shown in FIG. 12 may include two heat dissipation structures 610, 1212. The heat dissipation structure 1212 is disposed at the vertical side 604A of the duct portion 604. Similarly, the further duct portion 1106 may include two heat dissipation structures 1112, 1214. Additionally or alternatively, the duct portion 604 of the vapor chamber 1200 may further include a heat dissipation structure disposed at the horizontal side 604C of the duct portion 604. Additionally or alternatively, the duct portion 1106 of the vapor chamber 1200 may further include a heat dissipation structure disposed at a horizontal side of the duct portion 1106, opposite to the horizontal side having the heat dissipation structures 1112.

Various aspects of what is described here have provided a vapor chamber with improved performance, more efficient used of space and flexibility for implementation based on the number of heat sources and/or amount of heat to be dissipated.

Some of the subject matter and operations described in this specification can be implemented in digital electronic circuitry, or in computer software, firmware, or hardware, including the structures disclosed in this specification and their structural equivalents, or in combinations of one or more of them. Some of the subject matter described in this specification can be implemented as one or more computer programs, i.e., one or more modules of computer program instructions, encoded on a computer storage medium for execution by, or to control the operation of, data-processing apparatus. A computer storage medium can be, or can be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (e.g., multiple CDs, disks, or other storage devices).

Some of the operations described in this specification can be implemented as operations performed by a data processing apparatus on data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program, or in multiple coordinated files (e.g., files that store one or more modules, sub programs, or portions of code). A computer program can be deployed to be executed on one computer or on multiple computers that are located at one site or distributed across multiple sites and interconnected by a communication network.

Some of the processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application specific integrated circuit).

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of implementations have been described. Nevertheless, it will be understood that various modifications can be made. Accordingly, other implementations are within the scope of the following claims.

What is claimed is:

1. A vapor chamber, comprising:
a sealed enclosure comprising:
a main portion defining a main chamber, the main portion having a heat input surface region for contacting a heat source; and
a duct portion extending from a first margin region of the main portion and returning to a second margin region of the main portion, wherein the heat input surface region is between the first margin region and the second margin region of the main portion,
wherein the main portion and the duct portion form a closed loop structure.

2. The vapor chamber of claim 1, wherein at least one heat dissipation structure is disposed on a corresponding exterior surface of the duct portion of the vapor chamber.

3. The vapor chamber of claim 2, wherein the at least one heat dissipation structure is spaced apart from each other.

4. The vapor chamber of claim 2, wherein each of the at least one the heat dissipation structure comprises a fin structure.

5. The vapor chamber of claim 2,
wherein heat from the heat source in contact with the heat input surface region is transferred to a working fluid within the sealed enclosure via the heat input surface region to convert the working fluid from a liquid state to a gaseous state; and
wherein the working fluid in the gaseous state is condensed back into the liquid state along the duct portion of the vapor chamber, wherein an interior surface of the duct portion, which is opposite the corresponding exterior surface of the duct portion having the at least one heat dissipation structure, serves as a condensing surface.

6. The vapor chamber of claim 5, wherein a gas path is formed in a first direction from the main portion to the duct portion and a liquid path is formed in a second direction from the duct portion to the main portion.

7. The vapor chamber of claim 6, wherein the liquid path and the gas path form a closed loop path.

8. The vapor chamber of claim 1, wherein the closed loop structure is of a substantially rectangular annulus shape, wherein the main portion defines one side of the rectangular annulus shape and the duct portion defines remaining three sides of the rectangular annulus shape.

9. The vapor chamber of claim 1, wherein the main portion comprises:
a further heat input surface region adjacent to the heat input surface region on a side of the heat input surface region opposite the duct portion; and
a further duct portion extending from the first margin region of the main portion and returning to the second margin region of the main portion, wherein the further duct portion is at a side of the main portion opposite the duct portion, wherein the further heat input surface region is between the first margin region and the second margin region of the main portion,
wherein the main portion and the further duct portion form a further closed loop structure.

10. The vapor chamber of claim 9, wherein the further closed loop structure is a mirror image of the closed loop structure.

11. A heat dissipating assembly, comprising:
a fan unit; and
a vapor chamber surrounding the fan unit, the vapor chamber comprising:
a sealed enclosure comprising:
a main portion defining a main chamber, the main portion having a heat input surface region for contacting a heat source; and
a duct portion extending from a first margin region of the main portion and returning to a second margin region of the main portion, wherein the heat input surface region is between the first margin region and the second margin region of the main portion,
wherein the main portion and the duct portion form a closed loop structure to surround the fan unit.

12. The heat dissipating assembly of claim 11, wherein at least one heat dissipation structure is disposed on a corresponding exterior surface of the duct portion of the vapor chamber.

13. The heat dissipating assembly of claim 12, wherein the at least one heat dissipation structure is spaced apart from each other- and/or wherein each of the at least one the heat dissipation structure comprises a fin structure.

14. (canceled)

15. The heat dissipating assembly of claim 12,
wherein heat from the heat source in contact with the heat input surface region is transferred to a working fluid within the sealed enclosure via the heat input surface region to convert the working fluid from a liquid state to a gaseous state; and
wherein the working fluid in the gaseous state is condensed back into the liquid state along the duct portion of the vapor chamber, wherein an interior surface of the duct portion, which is opposite the corresponding exterior surface of the duct portion having the at least one heat dissipation structure, serves as a condensing surface.

16. The heat dissipating assembly of claim 15, wherein a gas path is formed in a first direction from the main portion to the duct portion and a liquid path is formed in a second direction from the duct portion to the main portion.

17. The heat dissipating assembly of claim 16, wherein the liquid path and the gas path form a closed loop path.

18. The heat dissipating assembly of claim 11, wherein the closed loop structure is of a substantially rectangular annulus shape, wherein the main portion defines one side of the rectangular annulus shape and the duct portion defines remaining three sides of the rectangular annulus shape.

19. The heat dissipating assembly of claim 11, wherein the main portion comprises:
a further heat input surface region adjacent to the heat input surface region on a side of the heat input surface region opposite the duct portion; and
a further duct portion extending from the first margin region of the main portion and returning to the second margin region of the main portion, wherein the further duct portion is at a side of the main portion opposite the duct portion, wherein the further heat input surface region is between the first margin region and the second margin region of the main portion,
wherein the main portion and the further duct portion form a further closed loop structure.

20. The heat dissipating assembly of claim 19, wherein the further closed loop structure is a mirror image of the closed loop structure.

21. An electronic device, comprising:
a heat generating electronic component;
a fan unit; and
a vapor chamber surrounding the fan unit, wherein the heat generating electronic component is in contact with a heat input surface region of the vapor chamber, the vapor chamber comprising:
a sealed enclosure comprising:
a main portion defining a main chamber, the main portion having the heat input surface region in contact with the heat source; and
a duct portion extending from a first margin region of the main portion and returning to a second margin region of the main portion, wherein the heat input surface region is between the first margin region and the second margin region of the main portion,
wherein the main portion and the duct portion form a closed loop structure to surround the fan unit.

22. (canceled)

23. (canceled)

24. (canceled)

25. (canceled)

26. (canceled)

27. (canceled)

28. (canceled)

29. (canceled)

30. (canceled)
